(19) United States
(12) Patent Application Publication
(10) Pub. No.: US 2026/0059947 A1
(43) Pub. Date: Feb. 26, 2026

(54) DISPLAY PANEL AND DISPLAY DEVICE

(71) Applicants: Hefei Visionox Technology Co., Ltd., Hefei (CN); Visionox Technology Inc., Kunshan (CN)

(72) Inventors: Xiaoxi SUN, Hefei (CN); Yingyu FENG, Kunshan (CN); Yuan YAO, Hefei (CN); Bo RAO, Hefei (CN); Yongqiang DU, Hefei (CN)

(73) Assignees: Hefei Visionox Technology Co., Ltd., Hefei (CN); Visionox Technology Inc., Kunshan (CN)

(21) Appl. No.: 19/306,978

(22) Filed: Aug. 21, 2025

(30) Foreign Application Priority Data
Aug. 23, 2024 (CN) 202411172530.4

(51) Int. Cl. H10K 59/122

(52) U.S. Cl. CPC H10K 59/122

(57) ABSTRACT

The present application discloses a display panel and a display device. The display panel includes: a substrate; an isolation structure disposed on one side of the substrate and enclosing isolation openings, where at least one film layer structure in the isolation structure has an arc edge and at least two straight edges on a side facing each isolation opening, the at least two straight edges having extension directions intersecting each other, and the arc edge being connected between two adjacent straight edges having extension directions intersecting each other. The display panel according to embodiments of the present application has better structural stability.

### CROSS REFERENCE TO RELATED APPLICATIONS

The present application claims priority to Chinese Patent Application No. 202411172530.4 filed on Aug. 23, 2024, and entitled “DISPLAY PANEL AND DISPLAY DEVICE”, which is incorporated herein by reference in its entirety.

### FIELD

The present application relates to the field of display, and in particular to a display panel and a display device.

### BACKGROUND

Organic light-emitting diodes (OLEDs) and flat panel display devices based on technologies such as light-emitting diodes (LEDs) have been widely applied to various consumer electronics such as mobile phones, televisions, notebook computers and desktop computers and predominate in display devices thanks to their advantages such as high image quality, energy efficiency, slim design and a wide range of applications.

However, the process performance of conventional OLED display products needs to be improved.

### SUMMARY

Embodiments of the present application provide a display panel and a display device, with the aim of improving the structural stability of the display panel.

An embodiment of the present application provides a display panel including: a substrate; an isolation structure disposed on one side of the substrate and enclosing isolation openings, where at least one film layer structure in the isolation structure has an arc edge and at least two straight edges on a side facing each isolation opening, the at least two straight edges having extension directions intersecting each other, and the arc edge being connected between two adjacent straight edges having extension directions intersecting each other, and the isolation structure includes first isolation portions and second isolation portions each located on a side of the first isolation portion facing away from the substrate, the second isolation portions protruding from the first isolation portions toward the isolation openings; and light-emitting devices at least partially located in the isolation openings and each including a first electrode, a light-emitting unit and a second electrode which are sequentially stacked in a direction away from the substrate, the second electrode being connected to the isolation structure.

An embodiment of the present application further provides a display panel including: a substrate; an isolation structure disposed on one side of the substrate and enclosing isolation openings, where the isolation structure includes first isolation portions and second isolation portions each located on a side of the first isolation portion facing away from the substrate, the second isolation portions protrude from the first isolation portions toward the isolation openings, and each of the first isolation portions has a first arc edge and at least two first straight edges on a side facing the isolation opening, the at least two first straight edges having extension directions intersecting each other, and the first arc edge being connected between two adjacent first straight edges having extension directions intersecting each other; and light-emitting devices at least partially located in the isolation openings and connected to the isolation structure.

An embodiment of the present application provides a display device including a display panel of any of the aforementioned embodiments.

A display panel according to an embodiment of the present application includes a substrate, an isolation structure, and light-emitting devices. The isolation structure is disposed on one side of the substrate and encloses isolation openings, and the light-emitting devices are at least partially located in the isolation openings. The isolation structure includes first isolation portions and second isolation portions each located on a side of the first isolation portion facing away from the substrate, and the second isolation portion protrudes from the first isolation portions toward the isolation openings. The isolation structure can be involved in the division of sub-pixels of the display panel. The light-emitting device includes a first electrode, a light-emitting unit and a second electrode which are sequentially stacked in a direction away from the substrate, the second electrode being connected to the isolation structure. At least one film layer structure in the isolation structure has an arc edge and at least two straight edges on a side facing each isolation opening, the at least two straight edges having extension directions intersecting each other. With the arrangement of the arc edge being connected between two adjacent straight edges having extension directions intersecting each other, that is, a corner between two adjacent straight edges having extension directions intersecting each other being configured as an arc edge, during patterning of a material of the isolation structure to form the isolation structure, an etching material is less likely to gather at the arc edge owing to the arc shape of the arc edge and is thus less likely to over-etch the material of the isolation structure, to better improve the structural stability of the display panel.

### BRIEF DESCRIPTION OF THE DRAWINGS

In order to describe the embodiments of the present application more clearly, the drawings required for illustration of the embodiments of the present application will be briefly introduced below. The drawings as described below are some of the embodiments of the present application, and other drawings can also be obtained from these drawings.

FIG. 1 is a structural schematic diagram of an isolation structure according to an embodiment of the present application;

FIG. 2 is a partial cross-sectional view of a display panel according to an embodiment of the present application;

FIG. 3 is a partial cross-sectional view of a display panel according to another embodiment of the present application;

FIG. 4 is a schematic partial enlarged view of an isolation structure according to an embodiment of the present application;

FIG. 5 is a schematic partial enlarged view of an isolation structure according to another embodiment of the present application;

FIG. 6 is a schematic partial enlarged view of an isolation structure according to yet another embodiment of the present application;

FIG. 7 is a schematic partial enlarged view of an isolation structure and a pixel defining layer according to an embodiment of the present application; and

FIG. 8 is a partial cross-sectional view of a display panel according to yet another embodiment of the present application.

### LIST OF REFERENCE SIGNS

10. Display panel;
100. Substrate; 110. Base substrate; 120. First insulation layer; 130. Second insulation layer; 140. Third insulation layer; 150. Drive circuit; 151. Transistor; 151a. Gate; 151b. Source/drain; 152. Storage capacitor; 152a. First plate; 152b. Second plate;
200. Pixel defining layer; 210. Pixel defining portion; 210a. Pixel opening; 211. Fourth arc edge; 212. Fourth straight edge;
300. Isolation structure; 300a. Isolation opening; 301. Arc edge; 302. Straight edge; 302a. First straight side edge; 302b. Second straight side edge; 302c. Bevel side edge; 310. First isolation portion; 311. First surface; 311a. First arc edge; 311b. First straight edge; 320. Second isolation portion; 321. Second surface; 321a. Second arc edge; 321b. Second straight edge; 330. Conductive portion; 331. Third surface; 331a. Third arc edge; 331b. Third straight edge;
400. Light-emitting device; 410. First electrode; 420. Light-emitting unit; 430. Second electrode;
500. Encapsulation layer; 510. First encapsulation layer; 520. Second encapsulation layer; 530. Third encapsulation layer;
L1. First length; L2. Second length; L3. Third length; LA. Fourth length;
G1. First spacing; G2. Second spacing; G3. Third spacing; G4. Fourth spacing;
a1. First angle; a2. Second angle;
X. First direction;
Y. Second direction;
Z. Thickness direction.

### DETAILED DESCRIPTION OF THE EMBODIMENTS

Embodiments of the present application will be described in detail below. In order to make the embodiments of the present application clearer, the present application will be further described in detail below with reference to the accompanying drawings and specific embodiments. It should be understood that the specific embodiments described herein are merely configured to explain the present application and are not configured to limit the present application. The present application may be implemented without some of these specific details. The following description of the embodiments is merely to provide a better understanding of the present application by illustrating examples of the present application.

It should be noted that, herein, relative terms such as “first” and “second” are only used to distinguish one entity or operation from another entity or operation, and do not necessarily require or imply that such an actual relationship or order exists between these entities or operations. Moreover, the terms “include”, “comprise”, or any other variants thereof are intended to cover a non-exclusive inclusion, and a process, a method, an article, or a device that includes a list of elements not only includes those elements but also includes other elements that are not listed, or further includes elements inherent to such a process, method, article, or device. If no more limitations are made, an element limited by “comprising/including . . . ” does not exclude other identical elements existing in the process, the method, the article, or the device which includes the element.

It should be understood that in the description of the structure of a component, a layer or region referred as being located “above” or “over” another layer or region may be directly on the other layer or region, or there may be other layers or regions between the layer or region and the other layer or region. Moreover, if the component is turned over, the layer or region is located “below” or “under” the other layer or region.

Embodiments of the present application provide a display panel and a display device. The embodiments of the display panel and the display device will be described below with reference to the drawings.

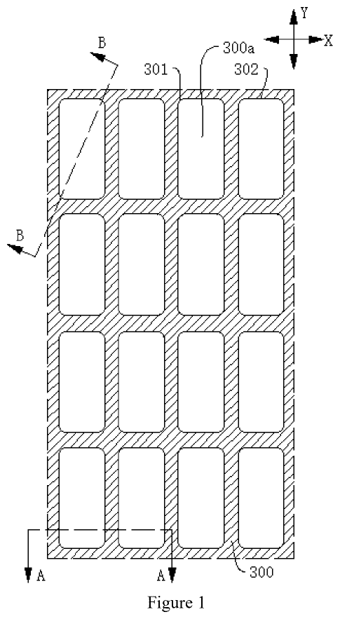

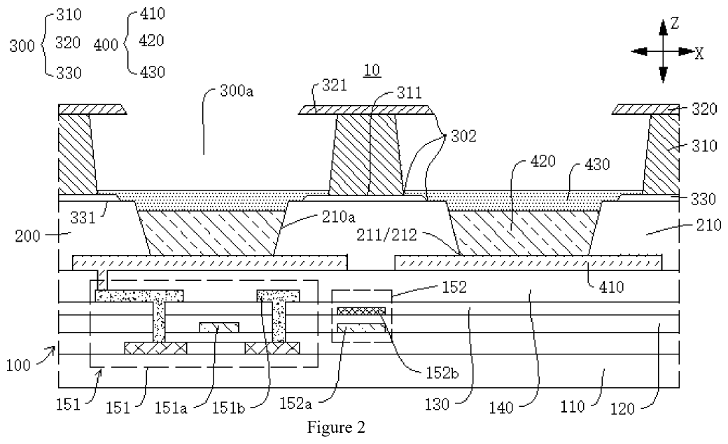

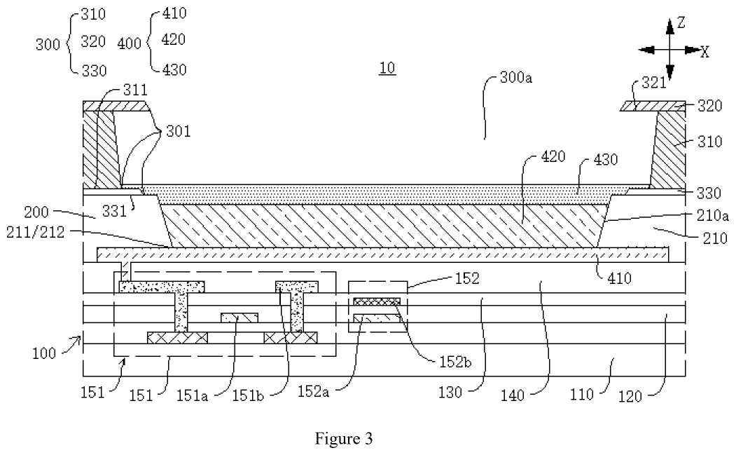

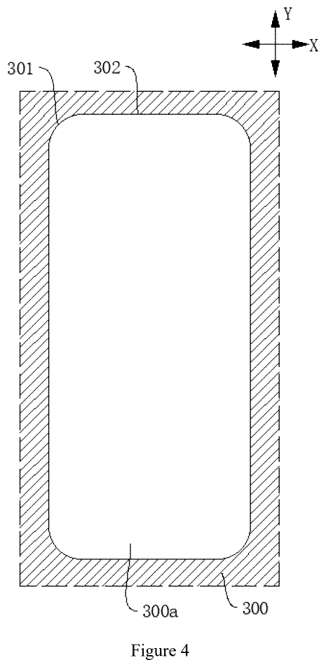

FIG. 1 is a structural schematic diagram of an isolation structure 300 according to an embodiment of the present application, FIG. 2 is a partial cross-sectional view of a display panel 10 according to an embodiment of the present application, FIG. 3 is a partial cross-sectional view of a display panel 10 according to another embodiment of the present application, and FIG. 4 is a schematic partial enlarged view of an isolation structure 300 according to an embodiment of the present application. An X direction in the figures may be a first direction, a Y direction in the figures may be a second direction, and a Z direction in the figures may be a thickness direction of the display panel 10. The first direction X, the second direction Y, and the thickness direction Z of the display panel 10 may intersect each other. In one embodiment, the first direction X, the second direction Y and the thickness direction Z of the display panel 10 may be perpendicular to each other. FIG. 2 may be a partial cross-sectional view of the display panel 10 taken along line A-A in FIG. 1, and FIG. 3 may be a partial cross-sectional view of the display panel 10 taken along line B-B in FIG. 1.

As shown in FIGS. 1 to 4, an embodiment of the present application provides a display panel 10, including: a substrate 100; an isolation structure 300 disposed on one side of the substrate 100 and enclosing isolation openings 300a, where at least one film layer structure in the isolation structure 300 has an arc edge 301 and at least two straight edges 302 on a side facing each isolation opening 300a, the at least two straight edges 302 having extension directions intersecting each other, and the arc edge 301 being connected between the two adjacent straight edges 302 having extension directions intersecting each other, and the isolation structure 300 includes first isolation portion 310 and second isolation portion 320 each located on a side of the first isolation portion 310 facing away from the substrate 100, the second isolation portion 320 protruding from the first isolation portions 310 toward the isolation openings 300a;

light-emitting devices 400 at least partially located in the isolation openings 300a, each light-emitting device 400 including a first electrode 410, a light-emitting unit 420 and a second electrode 430 which are sequentially stacked in a direction away from the substrate 100, the second electrode 430 being connected to the isolation structure 300.

According to a display panel 10 according to an embodiment of the present application, the display panel 10 includes a substrate 100, an isolation structure 300, and light-emitting devices 400. The isolation structure 300 is disposed on one side of the substrate 100 and encloses isolation openings 300a, and the light-emitting devices 400 are at least partially located in the isolation openings 300a. The isolation structure 300 includes first isolation portion 310 and second isolation portion 320 each located on a side of the first isolation portion 310 facing away from the substrate 100, and the second isolation portions 320 protrude from the first isolation portions 310 toward the isolation openings 300a. The isolation structure 300 can be involved in the division of sub-pixels of the display panel 10.

In one embodiment, the second isolation section 320 and the first isolation section are located facing a same isolation opening and on the same side, with the arrangement of the same second isolation portions 320 protruding from the first isolation portions 310 toward the isolation openings 300a, during evaporation of the light-emitting units 420 and the second electrodes 430 of the display panel 10, the second isolation portions 320 can shield at least part of the materials used to prepare the light-emitting units 420 and second electrodes 430 to partition the materials of the light-emitting units 420 and second electrodes 430 of adjacent sub-pixels, and can facilitate formation of light-emitting units 420 and second electrodes 430 disposed at intervals. In this way, it is not necessary to provide a mask having high precision during the evaporation of the light-emitting units 420 and second electrodes 430 of the display panel 10, for example, it is not necessary to provide a fine metal mask (FMM) during the evaporation of the light-emitting units 420 and second electrodes 430, to better effectively reduce the manufacturing cost of the display panel 10.

In one embodiment, the isolation structure 300 may be in a mesh shape, isolation openings 300a may be formed, and hollow areas in the isolation structure 300 in a mesh shape may form the isolation openings 300a.

In one embodiment, isolation openings 300a are formed, and the plurality of isolation openings 300a are disposed at intervals in the first direction X, and/or the plurality of isolation openings 300a are disposed at intervals in the second direction Y.

Each light-emitting device 400 includes a first electrode 410, a light-emitting unit 420 and a second electrode 430 which are sequentially stacked in the direction away from the substrate 100, and the second electrode 430 is connected to the isolation structure 300.

the isolation structure 300 is made of a material including a conductive material, and the second electrodes 430 are connected to the isolation structure 300, and the second electrodes 430 in adjacent isolation openings 300a may be electrically connected via the isolation structure 300, that is, the second electrodes 430 in adjacent isolation openings 300a may be connected to each other via the isolation structure 300 to form a surface electrode, to facilitate control on the second electrodes 430 in the display panel 10.

In one embodiment, the first isolation portion 310 may be made of a material including a conductive material, and the second electrode 430 may be connected to the first isolation portion 310, and the second electrodes 430 in adjacent isolation openings 300a may be electrically connected via the first isolation portion 310.

At least one film layer structure in the isolation structure 300 has an arc edge 301 and at least two straight edges 302 on a side facing the isolation opening 300a, and the at least two straight edges 302 have extension directions intersecting each other.

For each of the isolation opening 300a, the straight edge 302 may extend in a straight direction, and an orthographic projection of the straight edge 302 on the substrate 100 may be in the shape of a straight line and extend in the straight direction. In one embodiment, the arc edge 301 may extend in a straight direction, and an orthographic projection of the straight edge 302 on the substrate 100 may be in the shape of a straight line and extend in the straight direction.

In one embodiment, part of the straight edges 302 may extend in the first direction X and be disposed at intervals in the second direction Y, and the other straight edges 302 may extend in the second direction Y and be disposed at intervals in the first direction X. In one embodiment, the arc edge 301 may be connected between adjacent straight edge 302 extending in the first direction X and straight edge 302 extending in the second direction Y.

With the arrangement of the arc edge 301 being connected between two adjacent straight edges 302 having extension directions intersecting each other, that is, a corner between two adjacent straight edges 302 having extension directions intersecting each other being configured as an arc edge 301, during patterning of a material of the isolation structure 300 to form the isolation structure 300, an etching material is less likely to gather at the arc edge 301 owing to the arc shape of the arc edge 301 and is thus less likely to over-etch the isolation structure 300, to better improve the structural stability of the display panel 10.

In one embodiment, the etching material is less likely to over-etch the first isolation portion 310 at the arc edge owing to the arc shape of the arc edge 301, and the first isolation portion 310 is less likely to excessively retract inwards relative to the second isolation portion 320, which can facilitate the subsequent overlap and packaging of film layers. In one embodiment, this can facilitate the subsequent connection between the second electrode 430 and the isolation structure 300 to improve the connection effect between the second electrode 430 and the isolation structure 300 at the arc edge 301 and can facilitate the subsequent packaging of the light-emitting device 400.

For each of the isolation opening 300a, with the arrangement of the arc edge 301 being connected between two adjacent straight edges 302 having extension directions intersecting each other, the two adjacent straight edges 302 having extension directions intersecting each other can be connected via the arc edge 301 and form an arc corner, and compared with the direct connection of two adjacent straight edges 302 having extension directions intersecting each other, that is, compared with the corner between two adjacent straight edges 302 being a right-angle corner, the etching material can flow more easily at the arc corner formed by the arc edge 301 during the manufacturing process of the display panel 10, and the etching material is less likely to gather at the arc corner formed by the arc edge 301 and is thus less likely to over-etch the material of the first isolation portion 310 at the arc corner formed by the arc edge 301, which can thus facilitate the connection between the second electrode 430 and the first isolation portion 310, to improve the connection effect between the second electrode 430 and the first isolation portion 310.

In some embodiments, the substrate 100 may be configured in various forms. In one embodiment, the substrate 100 may include a base substrate 110 and a drive circuit 150 disposed on the base substrate 110. In one embodiment, the substrate 100 includes a first insulation layer 120, a second insulation layer 130 and a third insulation layer 140 which are stacked. In one embodiment, the third insulation layer 140 may serve as a planarization layer of a display panel 10. In one embodiment, the drive circuit 150 may include a transistor 151, a storage capacitor 152, and drive signal lines for connecting devices. The transistor 151 includes a semiconductor, a gate 151a and a source/drain 151b. The storage capacitor 152 includes a first plate 152a and a second plate 152b.

As an example, the gate 151a and the first plate 152a may be located on a side of the first insulation layer 120 facing the base substrate 110, the second plate 152b may be located between the first insulation layer 120 and the second insulation layer 130, and the source/drain 151b may be located between the second insulation layer 130 and the third insulation layer 140.

In one embodiment, the light-emitting unit 420 may include a hole inject layer (HIL), a hole transport layer (HTL), a light-emitting structure, an electron inject layer (EIL), and an electron transport layer (ETL).

In some embodiments, the first electrode 410 and the second electrode 430 may serve as pixel electrodes of the display panel 10. One of the first electrode 410 and the second electrode 430 may serve as an anode, and the other may serve as a cathode, and the light-emitting unit 420 is driven to emit light. The embodiments of the present application are described by taking the example in which the first electrode 410 is the anode of the display panel 10 and the second electrode 430 is the cathode of the display panel 10.

In some embodiments, the isolation structure 300 further includes conductive portions 330 each located on a side of the first isolation portion 310 facing the substrate 100, and the conductive portions 330 protrude from the first isolation portions 310 toward the isolation openings 300a.

In one embodiment, the second electrode 430 may be connected to the conductive portion 330, and the second electrodes 430 in adjacent isolation openings 300a may be electrically connected via the conductive portion 330.

In these embodiments, the arrangement of the conductive portions 330 protruding from the first isolation portions 310 toward the isolation openings 300a can facilitate the overlap between the second electrode 430 and the conductive portion 330, and can also better increase the overlap area between the second electrode 430 and the conductive portion 330, to reduce the resistance of the display panel 10.

In some embodiments of the present application, at least one film layer structure in the isolation structure 300 has an arc edge 301 and at least two straight edges 302 on the side facing the isolation opening 300a, that is, at least one of the first isolation portion 310, the second isolation portion 320 and the conductive portion 330 has an arc edge 301 and at least two straight edges 302 on the side facing the isolation opening 300a.

In some embodiments of the present application, straight edges 302 may be provided, and angles between the straight edges 302 may be reasonably set and the etching material is less likely to gather at the corners during the manufacturing process of the display panel 10.

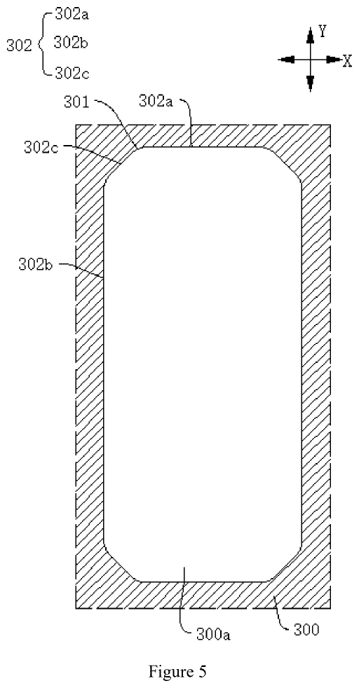

FIG. 5 is a schematic partial enlarged view of an isolation structure 300 according to another embodiment of the present application.

As shown in FIG. 5, in some embodiments, for an isolation opening 300a, the straight edges 302 include first straight side edges 302a, second straight side edges 302b, and bevel side edges 302c. The first straight side edges 302a extend in the first direction X and are disposed at intervals in the second direction Y, and the second straight side edges 302b extend in the second direction Y and are disposed at intervals in the first direction X. Each bevel side edge 302c is located between the first straight side edge 302a and the second straight side edge, and the bevel side edge 302c has a first angle a1 with the first straight side edge 302a, and/or the bevel side edge 302c has a second angle a2 with the second straight side edge 302b.

In one embodiment, the first angle a1 and/or the second angle a2 are/is greater than 90° and less than 180°. In one embodiment, the first angle a1 and/or the second angle a2 are/is 135°.

In one embodiment, at least part of the arc edges 301 are each connected between the first straight side edge 302a and the bevel side edge 302c, and/or at least part of the arc edges 301 are each connected between the second straight side edge 302b and the bevel side edge 302c.

In these embodiments, with the arrangement of straight edges 302 being provided and the angles between the straight edges 302 being reasonably set, for example, the first angle a1 and the second angle a2 being reasonably set, during the manufacturing process of the display panel 10, the possibility of the etching material remaining at the corners of the isolation structure 300 can be further reduced, to better improve the connection effect between the second electrode 430 and the isolation structure 300.

In one embodiment, adding the bevel side edges 302c can further facilitate the flow of the etching material during the manufacturing process of the display panel 10 and the etching material is less likely to gather at the corners between the first straight side edges 302a and the second straight side edges 302b during the manufacturing process of the display panel 10, and can also improve the connection effect between the second electrodes 430 and the isolation structure 300.

In some embodiments of the present application, the straight edges 302 of at least one of the first isolation portion 310, the second isolation portion 320 and the conductive portion 330 on the side facing the isolation opening 300a may include a first straight side edge 302a, a second straight side edge 302b and a bevel side edge 302c.

For ease of description, the following embodiments are described by taking the example in which the arc edge 301 is directly connected between the adjacent straight edge 302 extending in the first direction X and straight edge 302 extending in the second direction Y, that is, as shown in FIG. 4, the following embodiments are described by taking the example in which no bevel side edge 302c is provided between the adjacent straight edge 302 extending in the first direction X and straight edge 302 extending in the second direction Y.

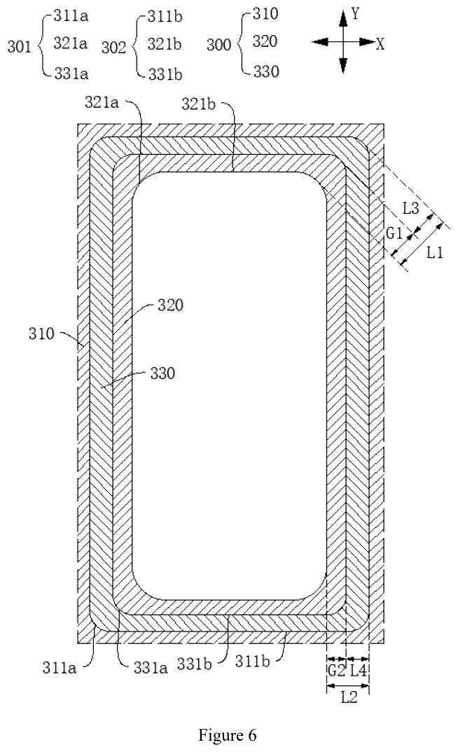

FIG. 6 is a schematic partial enlarged view of an isolation structure 300 according to yet another embodiment of the present application. FIG. 6 illustrates the width relationship of the film layer structures in the isolation structure 300 and the relative position relationship of the edges on the side of each film layer structure facing the isolation opening 300a, which do not represent the actual perspective relationship and stacking relationship of the film layer structures in the isolation structure 300.

As shown in FIG. 6, in some embodiments, each of the first isolation portions 310 has a first arc edge 311a and at least two first straight edges 311b on the side facing the isolation opening 300a, the at least two first straight edges 311b having extension directions intersecting each other, and the first arc edge 311a being connected between two adjacent first straight edges 311b having extension directions intersecting each other.

In one embodiment, the arc edge 301 may include the first arc edge 311a, and the straight edges 302 may include the first straight edges 311b.

In one embodiment, a cross-sectional area of each of the first isolation portions 310 gradually decreases in a direction away from the substrate 100, the first isolation portion 310 has a first surface 311 on a side facing the substrate 100, and each of the first surfaces 311 has a first arc edge 311a and a first straight edge 311b on the side facing the isolation opening 300a.

In one embodiment, each of the first isolation portions 310 has a first arc edge 311a and at least two first straight edges 311b on the side facing the isolation opening 300a, that is, each of the first surfaces 311 has a first arc edge 311a and at least two first straight edges 311b on the side facing the isolation opening 300a.

In these embodiments, with the arrangement of the first arc edge 311a being connected between two adjacent first straight edges 311b having extension directions intersecting each other, that is, the corner between two adjacent first straight edges 311b having extension directions intersecting each other being configured as the first arc edge 311a, during patterning of a material of the first isolation portion 310 to form the isolation structure 300, the etching material is less likely to gather at the first arc edge 311a owing to the arc shape of the first arc edge 311a and is thus less likely to over-etch the material of the first isolation portion 310, which can facilitate the overlap between the second electrode 430 and the first isolation portion 310 and can better improve the structural stability of the display panel 10.

In some embodiments, a radius of an orthographic projection of the first arc edge 311a on the substrate 100 is not less than 0.5 microns and not greater than 3 microns.

In one embodiment, the radius of the orthographic projection of the first arc edge 311a on the substrate 100 may be 0.5 microns, 1 micron, 1.5 microns, 2 microns, 2.5 microns, or 3 microns.

In one embodiment, a rounded corner angle of the orthographic projection of the first arc edge 311a on the substrate 100 is not less than 90° and not greater than 135°. In one embodiment, the rounded corner angle of the orthographic projection of the first arc edge 311a on the substrate 100 may be 90°, 100°, 110°, 120°, 130°, or 135°.

In these embodiments, with the reasonable setting of the shape and dimension of the first arc edge 311a, during the patterning of the material of the first isolation portion 310 to form the isolation structure 300, the etching material is less likely to gather at the first arc edge 311a and is thus less likely to over-etch the material of the first isolation portion 310, which can facilitate the overlap between the second electrode 430 and the first isolation portion 310 and can better improve the structural stability of the display panel 10.

In some embodiments, each of the second isolation portions 320 has a second arc edge 321a and at least two second straight edges 321b on the side facing the isolation opening 300a, the at least two second straight edges 321b have extension directions intersecting each other, and the second arc edge 321a is connected between two adjacent second straight edges 321b having extension directions intersecting each other.

In one embodiment, the arc edge 301 may include the second arc edge 321a, and the straight edges 302 may include the second straight edges 321b.

In one embodiment, the second arc edge 321a may be disposed corresponding to the first arc edge 311a, and the second straight edges 321b may be disposed corresponding to the first straight edges 311b. In one embodiment, the second isolation portion 320 at the second arc edge 321a may be located above the first isolation portion 310 at the first arc edge 311a, and the second isolation portion 320 at the second straight edge 321b may be located above the first isolation portion 310 at the first straight edge 311b.

In one embodiment, a cross-sectional area of each of the second isolation portions 320 gradually decreases in a direction away from the substrate 100, the second isolation portion 320 has a second surface 321 on a side facing the substrate 100, and each of the second surfaces 321 has a second arc edge 321a and a second straight edge 321b on the side facing the isolation opening 300a.

In one embodiment, each of the second isolation portions 320 has a second arc edge 321a and at least two second straight edges 321b on the side facing the isolation opening 300a, that is, each of the second surfaces 321 has a second arc edge 321a and at least two second straight edges 321b on the side facing the isolation opening 300a.

In these embodiments, with the arrangement of the second arc edge 321a being connected between two adjacent second straight edges 321b having extension directions intersecting each other, that is, the corner between two adjacent second straight edges 321b having extension directions intersecting each other being configured as the second arc edge 321a, the second isolation portion 320 at the second arc edge 321a may protrude an appropriate length toward the isolation opening 300a relative to the first isolation portion 310 at the first arc edge 311a, and during the manufacturing process of the display panel 10, the second isolation portion 320 at the second arc edge 321a can appropriately shield and partition the materials of the light-emitting unit 420 and the second electrode 430 to enable the materials of the light-emitting unit 420 and the second electrode 430 to be shielded and partitioned by the second isolation portions 320, and the second electrodes 430 can be better connected to other film layer structures of the isolation structure 300 below the second isolation portions 320, to better reduce the resistance of the display panel 10.

In some embodiments, a radius of an orthographic projection of the second arc edge 321a on the substrate 100 is not less than 0.5 microns and not greater than 3 microns.

In one embodiment, the radius of the orthographic projection of the second arc edge 321a on the substrate 100 may be 0.5 microns, 1 micron, 1.5 microns, 2 microns, 2.5 microns, or 3 microns.

In one embodiment, a rounded corner angle of the orthographic projection of the second arc edge 321a on the substrate 100 is not less than 90° and not greater than 135°. In one embodiment, the rounded corner angle of the orthographic projection of the second arc edge 321a on the substrate 100 may be 90°, 100°, 110°, 120°, 130°, or 135°.

In these embodiments, with the reasonably setting of the shape and dimension of the second arc edge 321a, the second isolation portion 320 at the second arc edge 321a may protrude an appropriate length toward the isolation opening 300a relative to the first isolation portion 310 at the first arc edge 311a, and the materials of the light-emitting unit 420 and the second electrode 430 can be shielded and partitioned by the second isolation portions 320, and the second electrodes 430 can be better connected to other film layer structures of the isolation structure 300 below the second isolation portions 320, to better reduce the resistance of the display panel 10.

In some embodiments, for an isolation opening 300a, the length of the second isolation portion 320 at the arc edge 301 protruding relative to a side of the first isolation portion 310 facing the isolation opening 300a is a first length L1, and the length of the second isolation portion 320 at the straight edge 302 protruding relative to the side of the first isolation portion 310 facing the isolation opening 300a is a second length L2. The first length L1 may be equal to or approximately equal to the second length L2.

In one embodiment, the first length L1 is greater than 0.98 times the second length L2 and less than 1.05 times the second length L2.

In one embodiment, a difference between the first length L1 and the second length L2 ranges from 0 to 0.2 microns.

In one embodiment, the length of the second isolation portion 320 at the arc edge 301 protruding relative to the side of the first isolation portion 310 facing the isolation opening 300a is the first length L1, that is, the length of the second isolation portion 320 at the second arc edge 321a protruding relative to the side of the first isolation portion 310 facing the isolation opening 300a is the first length L1. In one embodiment, the first length L1 may be the minimum spacing between the second arc edge 321a and an edge, on the side facing the isolation structure 300, of the surface on the side of the first isolation portion 310 facing away from the substrate 100.

In one embodiment, the length of the second isolation portion 320 at the straight edge 302 protruding relative to the side of the first isolation portion 310 facing the isolation opening 300a is the second length L2, that is, the length of the second isolation portion 320 at the second straight edge 321b protruding relative to the side of the first isolation portion 310 facing the isolation opening 300a is the second length L2. In one embodiment, the second length L2 may be the minimum spacing between the second straight edge 321b and an edge, on the side facing the isolation structure 300, of the surface on the side of the first isolation portion 310 facing away from the substrate 100.

In these embodiments, with the setting of the first length L1 being equal to or approximately equal to the second length L2, the length of the second isolation portion 320 at the second arc edge 321a protruding toward the isolation opening 300a relative to the first isolation portion 310 at the first arc edge 311a may be equal to or approximately equal to the length of the second electrode 430 and the second isolation portion 320 at the second straight edge 321b protruding toward the isolation opening 300a relative to the first isolation portion 310 at the first straight edge 311b, and the connection area between the second electrode 430 and other film layer structures of the isolation structure 300 below the second isolation portion 320 at the second arc edge 321a may be equal to or approximately equal to the connection area between the other film layer structures of the isolation structure 300 below the second isolation portion 320 at the second straight edge 321b, to enable the second electrode 430 in the isolation opening 300a to have better connection area with the isolation structure 300 at each position, and achieve better uniformity in connection area between the isolation structure 300 around the isolation opening 300a and the second electrode 430, which can improve the connection effect between the second electrode 430 and the isolation structure 300, to better reduce the resistance of the display panel 10.

In some embodiments, each of the conductive portions 330 has a third arc edge 331a and at least two third straight edges 331b on the side facing the isolation opening 300a, the at least two third straight edges 331b have extension directions intersecting each other, and the third arc edge 331a is connected between two adjacent third straight edges 331b having extension directions intersecting each other.

In one embodiment, the arc edge 301 may include the third arc edge 331a, and the straight edges 302 may include the third straight edges 331b.

In one embodiment, the third arc edge 331a may be disposed corresponding to the first arc edge 311a, and the third straight edges 331b may be disposed corresponding to the first straight edges 311b. In one embodiment, the conductive portion 330 at the third arc edge 331a may be located below the first isolation portion 310 at the first arc edge 311a, and the conductive portion 330 at the third straight edge 331b may be located below the first isolation portion 310 at the first straight edge 311b.

In one embodiment, a cross-sectional area of each of the conductive portions 330 gradually decreases in a direction away from the substrate 100, each of the conductive portions 330 has a third surface 331 on a side facing the substrate 100, and each of the third surfaces 331 has a third arc edge 331a and a third straight edge 331b on the side facing the isolation opening 300a.

In one embodiment, each of the conductive portions 330 has a third arc edge 331a and at least two third straight edges 331b on the side facing the isolation opening 300a, that is, each of the third surfaces 331 has a third arc edge 331a and at least two third straight edges 331b on the side facing the isolation opening 300a.

In these embodiments, with the arrangement of the third arc edge 331a is connected between two adjacent third straight edges 331b having extension directions intersecting each other, that is, the corner between two adjacent third straight edges 331b having extension directions intersecting each other being configured as the third arc edge 331a, during patterning of a material of the conductive portion 330 to form the isolation structure 300, the etching material is less likely to gather at the third arc edge 331a owing to the arc shape of the third arc edge 331a and is thus less likely to over-etch the material of the conductive portion 330, which can facilitate the overlap between the second electrode 430 and the conductive portion 330 and can better improve the structural stability of the display panel 10.

In some embodiments, a radius of an orthographic projection of the third arc edge 331a on the substrate 100 is not less than 0.5 microns and not greater than 3 microns.

In one embodiment, the radius of the orthographic projection of the third arc edge 331a on the substrate 100 may be 0.5 microns, 1 micron, 1.5 microns, 2 microns, 2.5 microns, or 3 microns.

In one embodiment, a rounded corner angle of the orthographic projection of the third arc edge 331a on the substrate 100 is not less than 90° and not greater than 135°. In one embodiment, the rounded corner angle of the orthographic projection of the third arc edge 331a on the substrate 100 may be 90°, 100°, 110°, 120°, 130°, or 135°.

In these embodiments, with the reasonable setting of the shape and dimension of the third arc edge 331a, during the patterning of the material of the conductive portion 330 to form the isolation structure 300, the etching material is less likely to gather at the third arc edge 331a and is thus less likely to over-etch the material of the conductive portion 330, which can facilitate the overlap between the second electrode 430 and the conductive portion 330 and can better improve the structural stability of the display panel 10.

In some embodiments, the length of the conductive portion 330 at the arc edge 301 protruding relative to the side of the first isolation portion 310 facing the isolation opening 300a is a third length L3, and the length of the conductive portion 330 at the straight edge 302 protruding relative to the side of the first isolation portion 310 facing the isolation opening 300a is a fourth length L4. The third length L3 may be equal to or approximately equal to the fourth length LA.

In one embodiment, a difference between the third length L3 and the fourth length L4 ranges from 0 to 0.2 microns.

In one embodiment, the length of the conductive portion 330 at the arc edge 301 protruding relative to the side of the first isolation portion 310 facing the isolation opening 300a is the third length L3, that is, the length of the conductive portion 330 at the third arc edge 331a protruding relative to the side of the first isolation portion 310 facing the isolation opening 300a is the third length L3. In one embodiment, the third length L3 may be the minimum spacing between the third arc edge 331a and the first arc edge 311a.

In one embodiment, the length of the conductive portion 330 at the straight edge 302 protruding relative to the side of the first isolation portion 310 facing the isolation opening 300a is the fourth length L4, that is, the length of the conductive portion 330 at the third straight edge 331b protruding relative to the side of the first isolation portion 310 facing the isolation opening 300a is the fourth length L4. In one embodiment, the fourth length L4 may be the minimum spacing between the third straight edge 331b and the first straight edge 311b.

In these embodiments, with the setting of the third length L3 is equal to or approximately equal to the fourth length L4, the length of the conductive portion 330 at the third arc edge 331a protruding toward the isolation opening 300a relative to the first isolation portion 310 at the first arc edge 311a may be equal to or approximately equal to the length of the conductive portion 330 at the third straight edge 331b protruding toward the isolation opening 300a relative to the first isolation portion 310 at the first straight edge 311b, and the connection area between the second electrode 430 and the conductive portion 330 at the third arc edge 331a may be equal to or approximately equal to the connection area between the second electrode 430 and the conductive portion 330 at the third straight edge 331b, to enable the second electrode 430 in the isolation opening 300a to have better connection area with the conductive portion 330 at each position, and also achieve better uniformity in connection area between the conductive portion 330 around the isolation opening 300a and the second electrode 430, which can improve the connection effect between the second electrode 430 and the conductive portion 330, to better reduce the resistance of the display panel 10.

In some embodiments, at the arc edge 301, a first spacing G1 is formed between an orthographic projection of an edge of the conductive portion 330 on the side facing the isolation opening 300a on the substrate 100 and an orthographic projection of an edge of the second isolation portion 320 on the side facing the isolation opening 300a on the substrate 100; and at the straight edge 302, a second spacing G2 is formed between the orthographic projection of the edge of the conductive portion 330 on the side facing the isolation opening 300a on the substrate 100 and the orthographic projection of the edge of the second isolation portion 320 on the side facing the isolation opening 300a on the substrate 100. The first spacing G1 may be equal to or approximately equal to the second spacing G2.

In one embodiment, at the arc edge 301, the first spacing G1 is formed between the orthographic projection of the edge of the conductive portion 330 on the side facing the isolation opening 300a on the substrate 100 and the orthographic projection of the edge of the second isolation portion 320 on the side facing the isolation opening 300a on the substrate 100, that is, the first spacing G1 is formed between the orthographic projection of the second arc edge 321a on the substrate 100 and the orthographic projection of the third arc edge 331a on the substrate 100.

In one embodiment, at the straight edge 302, the second spacing G2 is formed between the orthographic projection of the edge of the conductive portion 330 on the side facing the isolation opening 300a on the substrate 100 and the orthographic projection of the edge of the second isolation portion 320 on the side facing the isolation opening 300a on the substrate 100, that is, the second spacing G2 is formed between the orthographic projection of the second straight edge 321b on the substrate 100 and the orthographic projection of the third straight edge 331b on the substrate 100.

In one embodiment, the first spacing G1 ranges from 0.3 microns to 0.7 microns, and/or the second spacing G2 ranges from 0.3 microns to 0.7 microns.

In one embodiment, the difference between the first spacing G1 and the second spacing G2 ranges from 0 to 0.2 microns.

In these embodiments, with the reasonable setting of the first spacing G1 and the second spacing G2, during the manufacturing process of the display panel 10, the materials of the light-emitting unit 420 and the second electrode 430 can be appropriately shielded and partitioned by the second arc edge 321a and the second isolation portion 320 at the second straight edge 321b, and it is also may be to allow the material of the second electrode 430 to fall above the second arc edge 321a and above the conductive portion 330 at the second straight edge 321b, which can better improve the connection area between the second electrode 430 and the isolation structure 300, to better reduce the resistance of the display panel 10.

In addition, with the setting of the first spacing G1 is equal to or approximately equal to the second spacing G2, during the manufacturing process of the display panel 10, the second arc edge 321a and the second isolation structure 300 at the second straight edge 321b have the same or similar shielding effect on the material of the second electrode 430 that falls on the third arc edge 331a and the conductive portion 330 at the third straight edge 331b, and the connection area between the second electrode 430 and the conductive portion 330 at the third arc edge 331a may be equal to or approximately equal to the connection area between the second electrode 430 and the conductive portion 330 at the third straight edge 331b, to enable the second electrode 430 in the isolation opening 300a to have better connection area with the conductive portion 330 at each position, and also achieve better uniformity in connection area between the conductive portion 330 around the isolation opening 300a and the second electrode 430, which can improve the connection effect between the second electrode 430 and the conductive portion 330, to better reduce the resistance of the display panel 10.

In some embodiments, the display panel 10 further includes a pixel defining layer 200 disposed on one side of the substrate 100. The pixel defining layer 200 includes pixel defining portions 210, and each pixel defining portion 210 encloses a pixel opening 210a in communication with the isolation opening 300a. The pixel defining layer 200 may also be involved in the division of sub-pixels of the display panel 10.

In one embodiment, the isolation structure 300 may be located on a side of the pixel defining portions 210 facing away from the substrate 100.

In one embodiment, part of the structure of the light-emitting device 400 is located in the pixel opening 210a, and another part of the structure of the light-emitting device 400 may be located in the isolation opening 300a.

In one embodiment, the pixel defining portion 210 may partially cover the first electrode 410, and part of the first electrode 410 may be exposed from the pixel opening 210a and in contact with the light-emitting unit 420 to enable the first electrode 410 to drive the light-emitting unit 420 to emit light.

In one embodiment, the light-emitting unit 420 and the second electrode 430 may be partially located in the pixel opening 210a, and the light-emitting unit 420 and the second electrode 430 may partially extend outwards from the pixel opening 210a. The second electrode 430 may partially extend outwards from the pixel opening 210a and be connected to the isolation structure 300.

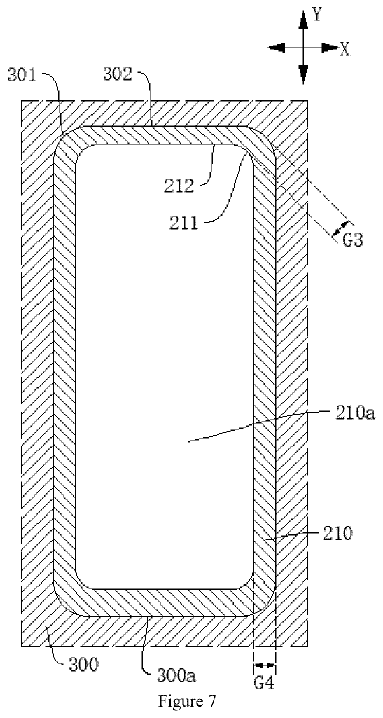

FIG. 7 is a schematic partial enlarged view of an isolation structure 300 and a pixel defining layer 200 according to an embodiment of the present application.

As shown in FIG. 7, in some embodiments, the pixel defining portion 210 has a fourth arc edge 211 and at least two fourth straight edges 212 on a side facing the pixel opening 210a, the at least two fourth straight edges 212 have extension directions intersecting each other, and the fourth arc edge 211 is connected between two adjacent fourth straight edges 212 having extension directions intersecting each other.

In one embodiment, the pixel defining portion 210 has a fourth arc edge 211 and at least two fourth straight edges 212 on a side facing the pixel opening 210a, that is, the surface of the pixel defining portion 210 in contact with the first electrode 410 has a fourth arc edge 211 and at least two fourth straight edges 212 on a side facing the pixel opening 210a.

In one embodiment, the fourth arc edge 211 may be disposed corresponding to the first arc edge 311a, and the fourth straight edge 212 may be disposed corresponding to the first straight edge 311b. In one embodiment, the pixel defining portion 210 at the fourth arc edge 211 may be located below the first isolation portion 310 at the first arc edge 311a, and the pixel defining portion 210 at the fourth straight edge 212 may be located below the first isolation portion 310 at the first straight edge 311b.

In one embodiment, part of the fourth straight edges 212 extend in the first direction X and are disposed at intervals in the second direction Y, and other part of the fourth straight edges 212 extend in the second direction Y and are disposed at intervals in the first direction X, and each fourth arc edge 211 is disposed corresponding to the first arc edge 311a, and each fourth straight edge 212 is disposed corresponding to the first straight edge 311b.

In these embodiments, with the arrangement of the fourth arc edge 211 is connected between two adjacent fourth straight edges 212 having extension directions intersecting each other, that is, the corner between two adjacent fourth straight edges 212 having extension directions intersecting each other being configured as the fourth arc edge 211, the pixel defining portion 210 at the fourth arc edge 211 may have an appropriate spacing relative to the isolation structure 300 at the arc edge 301, which can facilitate the connection between the second electrode 430 extending from the pixel opening 210a at the fourth arc edge 211 and the isolation structure 300 at the arc edge 301, which achieves better connection area between the second electrode 430 extending from the pixel opening 210a at the fourth arc edge 211 and the isolation structure 300 at the arc edge 301, to better reduce the resistance of the display panel 10.

In some embodiments, a third spacing G3 is formed between the orthographic projection of the arc edge 301 on the substrate 100 and the orthographic projection of the fourth arc edge 211 on the substrate 100, and a fourth spacing G4 is formed between the orthographic projection of the straight edge 302 on the substrate 100 and the orthographic projection of the fourth straight edge 212 on the substrate 100. The third spacing G3 may be equal to or approximately equal to the fourth spacing G4.

In one embodiment, the difference between the third spacing G3 and the fourth spacing G4 ranges from 0 to 0.2 microns.

In one embodiment, the third spacing G3 is formed between the orthographic projection of the arc edge 301 on the substrate 100 and the orthographic projection of the fourth arc edge 211 on the substrate 100, that is, the third spacing G3 is formed between the orthographic projection of any one of the first arc edge 311a, the second arc edge 321a or the third arc edge 331a on the substrate 100 and the orthographic projection of the fourth arc edge 211 on the substrate 100.

In one embodiment, the fourth spacing G4 is formed between the orthographic projection of the straight edge 302 on the substrate 100 and the orthographic projection of the fourth straight edge 212 on the substrate 100, that is, the fourth spacing G4 is formed between the orthographic projection of any one of the first straight edge 311b, the second straight edge 321b or the third straight edge 331b on the substrate 100 and the orthographic projection of the fourth straight edge 212 on the substrate 100.

In these embodiments, with the setting of the third spacing G3 is equal to or approximately equal to the fourth spacing G4, the spacing between the fourth arc edge 211 of the pixel defining portion 210 and the arc edge 301 of the isolation structure 300 may be equal to or approximately equal to the spacing between the fourth straight edge 212 of the pixel defining portion 210 and the straight edge 302 of the isolation structure 300, and the connection area between the second electrode 430 extending from above the pixel opening 210a at the fourth arc edge 211 and the isolation structure 300 at the arc edge 301 may be equal to or approximately equal to the connection area between the second electrode 430 extending from above the pixel opening 210a at the fourth straight edge 212 and the isolation structure 300 at the straight edge 302, to enable the second electrode 430 in the isolation opening 300a to have better connection area with the conductive portion 330 at each position, and achieve better uniformity in connection area between the conductive portion 330 around the isolation opening 300a and the second electrode 430, which can improve the connection effect between the second electrode 430 and the conductive portion 330, to better reduce the resistance of the display panel 10.

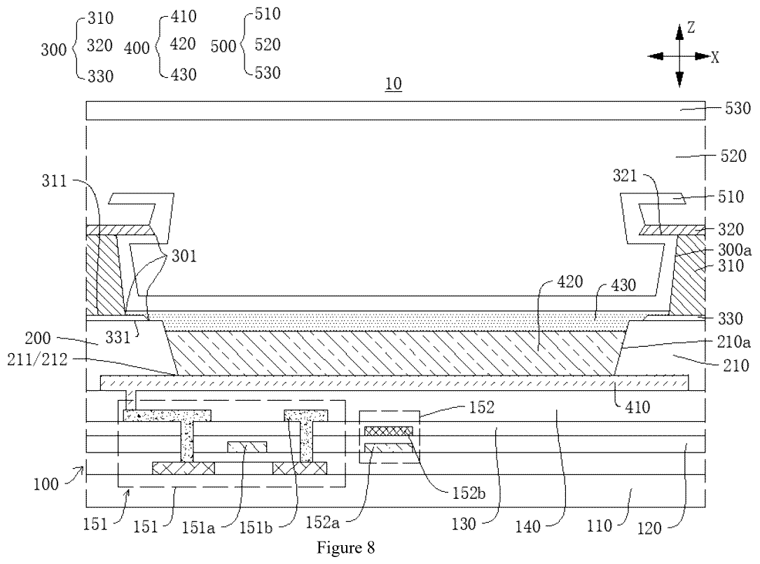

FIG. 8 is a partial cross-sectional view of a display panel 10 according to yet another embodiment of the present application.

As shown in FIG. 8, in some embodiments, the display panel 10 further includes an encapsulation layer 500 disposed on a side of the isolation structure 300 and the light-emitting device 400 facing away from the substrate 100. The encapsulation layer 500 can be used to implement encapsulation of the display panel 10.

In one embodiment, the encapsulation layer 500 may include a first encapsulation layer 510 disposed on a side of the isolation structure 300 and the light-emitting device 400 facing away from the substrate 100. In one embodiment, the first encapsulation layer 510 may be made of a material including an inorganic material, and the first encapsulation layer 510 can better effectively reduce the impact of water vapor on the operation of the light-emitting device 400. In one embodiment, the first encapsulation layer 510 may be formed by a chemical vapor deposition (CVD) process.

In one embodiment, the encapsulation layer 500 further includes a second encapsulation layer 520 located on a side of the first encapsulation layer 510 facing away from the substrate 100, to better improve the encapsulation effect of the display panel 10. In one embodiment, the second encapsulation layer 520 may be made of a material including an organic material, and during the manufacturing process of the display panel 10, the second encapsulation layer 520 may have better fluidity, and the surface of the second encapsulation layer 520 facing away from the substrate 100 may have better flatness, which can facilitate the subsequent formation of film layers. In one embodiment, the second encapsulation layer 520 may be prepared by inkjet printing (IJP).

In one embodiment, the encapsulation layer 500 may further include a third encapsulation layer 530 located on a side of the second encapsulation layer 520 facing away from the substrate 100, to better improve the encapsulation effect of the display panel 10. In one embodiment, the third encapsulation layer 530 may be made of a material including an inorganic material, and the third encapsulation layer 530 can better effectively reduce the impact of water vapor on the operation of the light-emitting device 400. In one embodiment, the third encapsulation layer 530 may be prepared by a chemical vapor deposition process.

In some embodiments of the present application, with the arrangement of the arc edge 301 is connected between two adjacent straight edges 302 having extension directions intersecting each other, that is, the corner between two adjacent straight edges 302 having extension directions intersecting each other being configured as the arc edge 301, during patterning of the material of the isolation structure 300 to form the isolation structure 300, the etching material is less likely to over-etch the first isolation portion 310 at the arc edge owing to the arc shape of the arc edge 301, and thus the first isolation portion 310 is less likely to excessively retract inwards relative to the second isolation portion 320, and during the manufacturing process of the display panel 10, the material of the encapsulation layer 500 can be easily attached to the surface of the isolation structure 300, for example, the material of the first encapsulation layer 510 can be easily attached to the surface of the first isolation portion 310, which can improve the encapsulation effect of the display panel 10 to enable the encapsulation layer 500 to better limit the damage of the etching material to the light-emitting device 400 during the etching manufacturing process of the display panel 10.

Referring to FIGS. 1 to 8, an embodiment of the present application further provides a display panel 10 including: a substrate 100; an isolation structure 300 disposed on one side of the substrate 100 and enclosing isolation openings 300a, where the isolation structure 300 includes first isolation portions 310 and second isolation portions 320 each located on a side of the first isolation portion 310 facing away from the substrate 100, the second isolation portions 320 protrude from the first isolation portions 310 toward the isolation openings 300a, and each of the first isolation portions 310 has a first arc edge 311a and at least two first straight edges 311b on a side facing the isolation opening 300a, the at least two first straight edges 311b having extension directions intersecting each other, and the first arc edge 311a is connected between two adjacent first straight edges 311b having extension directions intersecting each other; and light-emitting devices 400 at least partially located in the isolation openings 300a and connected to the isolation structure 300.

According to a display panel 10 according to an embodiment of the present application, the display panel 10 includes a substrate 100, an isolation structure 300, and light-emitting devices 400. The isolation structure 300 is disposed on one side of the substrate 100 and encloses isolation openings 300a, the light-emitting devices 400 are at least partially located in the isolation openings 300a and connected to the isolation structure 300, and the isolation structure 300 can be involved in the division of sub-pixels of the display panel 10.

The isolation structure 300 includes first isolation portions 310 and second isolation portions 320 each located on a side of the first isolation portion 310 facing away from the substrate 100, and the second isolation portions 320 protrude from the first isolation portions 310 toward the isolation openings 300a.

In one embodiment, the light-emitting device 400 may include a first electrode 410, a light-emitting unit 420 and a second electrode 430 in any of the aforementioned embodiments. With the arrangement of the second isolation portions 320 protruding from the first isolation portions 310 toward the isolation openings 300a, during evaporation of the light-emitting units 420 and the second electrodes 430 of the display panel 10, the second isolation portions 320 can shield at least part of the materials used to prepare the light-emitting units 420 and second electrodes 430, to partition the materials of the light-emitting units 420 and second electrodes 430 of adjacent sub-pixels and facilitate formation of light-emitting units 420 and second electrodes 430 disposed at intervals. In this way, it is not necessary to provide a mask having high precision during the evaporation of the light-emitting units 420 and second electrodes 430 of the display panel 10, for example, it is not necessary to provide a fine metal mask (FMM) during the evaporation of the light-emitting units 420 and second electrodes 430, to better effectively reduce the manufacturing cost of the display panel 10.

With the arrangement of the first arc edge 311a is connected between two adjacent first straight edges 311b having extension directions intersecting each other, that is, the corner between two adjacent first straight edges 311b having extension directions intersecting each other being configured as the first arc edge 311a, during patterning of a material of the first isolation portion 310 to form the isolation structure 300, the etching material is less likely to gather at the first arc edge 311a owing to the arc shape of the first arc edge 311a and is thus less likely to over-etch the material of the first isolation portion 310, which can facilitate the overlap between the second electrode 430 and the first isolation portion 310 and can better improve the structural stability of the display panel 10.

In one embodiment, a display panel 10 according to an embodiment of the present application may be the display panel 10 in any of the aforementioned embodiments, and thus a display panel 10 according to an embodiment of the present application may have the structure and beneficial effects of the display panel 10 in any of the aforementioned embodiments, which will not be described in detail in the present application.

In one embodiment, the substrate 100 may be the substrate 100 in any of the aforementioned embodiments. In one embodiment, the light-emitting device 400 may be the light-emitting device 400 in any of the aforementioned embodiments. In one embodiment, the first electrode 410 and the second electrode 430 may serve as an anode and a cathode of the display panel 10, respectively. In one embodiment, the isolation structure 300 may be the isolation structure 300 in any of the aforementioned embodiments, the isolation structure 300 may enclose the isolation opening 300a in any of the aforementioned embodiments, and the isolation structure 300 may include the first isolation portion 310, the second isolation portion 320 and the conductive portion 330 in any of the aforementioned embodiments.

In one embodiment, the display panel 10 may further include the pixel defining layer 200 of any of the aforementioned embodiments, the pixel defining layer 200 may include the pixel defining portion 210 of any of the aforementioned embodiments, the pixel defining portion 210 may have the fourth arc edge 211 and the fourth straight edge 212 of any of the aforementioned embodiments, and the relative position relationship between the pixel defining portion 210 and the isolation structure 300 may also be set with reference to the aforementioned embodiments.

The relevant structural composition, manufacturing methods, etc. of the isolation structure (also referred to as a partition structure, etc.) are recited in patent (applications) PCT/CN2023/134518, 202310759370.2, 202310740412.8, 202310707209.0, and 202311346196.5, the contents of which are incorporated herein by reference.

An embodiment of the present application provides a display device including a display panel 10 of any of the aforementioned implementations. Since the display device according to an embodiment of the present application includes the display panel 10 of any one of the above embodiments of the present application, the display device according to one embodiment of the present application has the beneficial effects of the display panel 10 of any one of the above embodiments of the present application, and will not be described in detail here.

The display device in the embodiments of the present application includes, but is not limited to, devices having a display function, such as a mobile phone, a personal digital assistant (PDA), a tablet computer, an e-book reader, a television, an access control system, a smart fixed-line telephone, or a console.

The embodiments of the present application as described above neither set forth all the details, nor do they limit the present application to only the described specific embodiments. Apparently, many modifications and variations can be made in light of the above description. The embodiments are selected and described in this specification to better explain the principles and practical applications of the present application, good use of the present application can be made and modify and use the present application. The present application is limited only by the claims and all the scopes and equivalents thereof.

1. A display panel, comprising:
a substrate;
an isolation structure disposed on one side of the substrate and enclosing a plurality of isolation openings;
wherein at least one film layer structure in the isolation structure has an arc edge and at least two straight edges on a side facing an corresponding isolation opening of the plurality of isolation openings, the at least two straight edges have extension directions intersecting each other, and the arc edge is connected between two adjacent straight edges of the least two straight edges having extension directions intersecting each other, and the isolation structure comprises a first isolation portion and a second isolation portion located on a side of the first isolation portion facing away from the substrate, the second isolation portion protruding from the first isolation portion toward the corresponding isolation openings; and
light-emitting devices at least partially located in the isolation openings, and each of the light-emitting devices comprises a first electrode, a light-emitting unit and a second electrode, the first electrode, the light-emitting unit and the second electrode are sequentially stacked in a direction away from the substrate, the second electrode is connected to the isolation structure.

2. The display panel according to claim 1, wherein part of the at least two straight edges extend in a first direction and are disposed at intervals in a second direction, and the other straight edges extend in the second direction and are disposed at intervals in the first direction, the first direction, the second direction, and a thickness direction of the display panel intersecting each other.

3. The display panel according to claim 2, wherein the plurality of isolation openings are disposed at intervals in the first direction, or the plurality of isolation openings are disposed at intervals in the second direction.

4. The display panel according to claim 1, wherein the at least two straight edges comprise at least one of first straight side edges, at least one of second straight side edges, and at least one of bevel side edges, at least one of the first straight side edges extending in the first direction and being disposed at intervals in the second direction, at least one of the second straight side edges extending in the second direction and being disposed at intervals in the first direction, and each of the bevel side edges is located between the first straight side edge and the second straight side edge, wherein the bevel side edge has a first angle with the first straight side edge, and the bevel side edge has a second angle with the second straight side edge; and
the first angle or the second angle is greater than 90° and less than 180°.

5. The display panel according to claim 4, wherein at least one film layer structure in the isolation structure has a plurality of arc edges on a side facing an corresponding isolation opening of the plurality of isolation openings, a part of the arc edges are each connected between the first straight side edge and bevel side edge, and another part of the arc edges are each connected between the second straight side edge and bevel side edge.

6. The display panel according to claim 1, wherein each of the first isolation portions has a first arc edge and at least two first straight edges on a side facing the isolation opening, the at least two first straight edges having extension directions intersecting each other, at least one of the first straight side edges comprises two adjacent first straight edges having extension directions intersecting each other, and the first arc edge is connected between the two adjacent first straight edges;
a cross-sectional area of each of the first isolation portions gradually decreases in a direction away from the substrate, and the first isolation portion has a first surface on a side facing the substrate, the first surface having the first arc edge and the first straight edges on the side facing the isolation opening; and
a radius of an orthographic projection of the first arc edge on the substrate is not less than 0.5 microns and not greater than 3 microns.

7. The display panel according to claim 6, wherein a rounded corner angle of the orthographic projection of the first arc edge on the substrate is not less than 90° and not greater than 135°.

8. The display panel according to claim 1, wherein the second isolation portion has a second arc edge and at least two second straight edges on the side facing the isolation opening, the at least two second straight edges having extension directions intersecting each other, and the second arc edge is connected between two adjacent second straight edges of the at least two second straight edges having extension directions intersecting each other; a cross-sectional area of each of the second isolation portions gradually decreases in a direction away from the substrate, and the second isolation portion has a second surface on a side facing the substrate, the second surface having the second arc edge and the at least two second straight edges on the side facing the corresponding isolation opening; and
a radius of an orthographic projection of the second arc edge on the substrate is not less than 0.5 microns and not greater than 3 microns.

9. The display panel according to claim 8, wherein a rounded corner angle of the orthographic projection of the second arc edge on the substrate is not less than 90° and not greater than 135°.

10. The display panel according to claim 1, wherein a length of the second isolation portion at the arc edge protruding relative to a side of the first isolation portion facing the corresponding isolation opening is a first length, and a length of the second isolation portion at the straight edge protruding relative to the side of the first isolation portion facing the corresponding isolation opening is a second length, wherein the first length is greater than 0.98 times the second length and less than 1.05 times the second length; and a difference between the first length and the second length ranges from 0 to 0.2 microns.

11. The display panel according to claim 1, wherein the isolation structure further comprises a conductive portions located on a side of the first isolation portion facing the substrate, wherein the conductive portion protrude from the first isolation portion toward the corresponding isolation opening; and
the conductive portion has a third arc edge and at least two third straight edges on the side facing the corresponding isolation opening, the at least two third straight edges having extension directions intersecting each other, and the third arc edge is connected between two adjacent third straight edges of the at least two third straight edges having extension directions intersecting each other.

12. The display panel according to claim 11, wherein a cross-sectional area of each of the conductive portions gradually decreases in a direction away from the substrate, and the conductive portion has a third surface on a side facing the substrate, the third surface having the third arc edge and the at least two third straight edges on the side facing the isolation opening;
a radius of an orthographic projection of the third arc edge on the substrate is not less than 0.5 microns and not greater than 3 microns; and
a rounded corner angle of the orthographic projection of the third arc edge on the substrate is not less than 90° and not greater than 135°.

13. The display panel according to claim 11, wherein a length of the conductive portion at the arc edge protruding relative to the side of the first isolation portion facing the corresponding the isolation opening is a third length, and a length of the conductive portion at the straight edge protruding relative to the side of the first isolation portion facing one of the isolation openings is a fourth length, wherein a difference between of the third length and the fourth length ranges from 0 to 0.2 microns.

14. The display panel according to claim 11, wherein at the arc edge, a first spacing is formed between an orthographic projection of an edge of the conductive portion on the side facing the isolation opening on the substrate and an orthographic projection of an edge of the second isolation portion on the side facing the isolation opening on the substrate, the first spacing ranging from 0.3 microns to 0.7 microns, and
at one of the straight edges, a second spacing is formed between the orthographic projection of the edge of the conductive portion on the side facing the isolation opening on the substrate and the orthographic projection of the edge of the second isolation portion on the side facing the isolation opening on the substrate, the second spacing ranging from 0.3 microns to 0.7 microns;
wherein a difference between the first spacing and the second spacing ranges from 0 to 0.2 microns.

15. The display panel according to claim 1, further comprising a pixel defining layer disposed on one side of the substrate, wherein the pixel defining layer comprises a pixel defining portion and a plurality of pixel openings, the pixel defining portion enclosing the plurality of pixel openings, the plurality of pixel openings are in communication with the corresponding plurality of isolation openings.

16. The display panel according to claim 10, wherein the pixel defining portion has a fourth arc edge and at least two fourth straight edges on a side facing each of the pixel openings, the at least two fourth straight edges having extension directions intersecting each other, and the fourth arc edge is connected between two adjacent fourth straight edges of the at least two straight edges having extension directions intersecting each other.

17. The display panel according to claim 16, wherein part of the fourth straight edges extend in the first direction and are disposed at intervals in the second direction, and the other fourth straight edges extend in the second direction and are disposed at intervals in the first direction, the first direction, the second direction, and a thickness direction of the display panel intersecting each other.

18. The display panel according to claim 16, wherein a third spacing is formed between an orthographic projection of the arc edge on the substrate and an orthographic projection of the fourth arc edge on the substrate, and a fourth spacing is formed between an orthographic projection of one of the straight edges on the substrate and an orthographic projection of one of the fourth straight edges on the substrate, wherein a difference between the third spacing and the fourth spacing ranges from 0 to 0.2 microns.

19. A display panel, comprising:
a substrate;
an isolation structure disposed on one side of the substrate and enclosing a plurality of isolation openings, wherein the isolation structure comprises a first isolation portion and a second isolation portion located on a side of the first isolation portion facing away from the substrate, the second isolation portion protrude from the first isolation portion toward an corresponding isolation opening of the plurality of isolation openings, and the first isolation portion has a first arc edge and at least two first straight edges on a side facing the corresponding isolation opening, the at least two first straight edges having extension directions intersecting each other, and the first arc edge is connected between two adjacent first straight edges having extension directions intersecting each other; and
light-emitting devices at least partially located in the isolation openings and connected to the isolation structure.

20. A display device, comprising a display panel, wherein the display panel comprising:
a substrate;
an isolation structure disposed on one side of the substrate and enclosing a plurality of isolation openings;
wherein at least one film layer structure in the isolation structure has an arc edge and at least two straight edges on a side facing an corresponding isolation opening of the plurality of isolation openings, the at least two straight edges have extension directions intersecting each other, and the arc edge is connected between two adjacent straight edges of the at least two straight edges having extension directions intersecting each other, and the isolation structure comprises a first isolation portion and a second isolation portion located on a side of the first isolation portion facing away from the substrate, the second isolation portion protruding from the first isolation portion toward the corresponding isolation openings; and
light-emitting devices at least partially located in the isolation openings, and each of the light-emitting devices includes a first electrode, a light-emitting unit and a second electrode, the first electrode, the light-emitting unit and the second electrode are sequentially stacked in a direction away from the substrate, the second electrode is connected to the isolation structure.
